(19) United States
(12) Patent Application Publication
(10) Pub. No.: US 2025/0183850 A1
(43) Pub. Date: Jun. 5, 2025

(54) DOHERTY AMPLIFIER CIRCUIT

(71) Applicant: Sumitomo Electric Device Innovations, Inc., Yokohama-shi (JP)

(72) Inventor: Takashi SUMIYOSHI, Yokohama-shi (JP)

(73) Assignee: Sumitomo Electric Device Innovations, Inc., Yokohama-shi (JP)

(21) Appl. No.: 18/956,952

(22) Filed: Nov. 22, 2024

(30) Foreign Application Priority Data
Nov. 30, 2023 (JP) 2023-202824

(51) Int. Cl. H03F 1/02; H03F 1/56; H03F 3/213

(52) U.S. Cl. CPC H03F 1/0288; H03F 1/56; H03F 3/213; H03F 2200/222; H03F 2200/387

(57) ABSTRACT

A Doherty amplifier circuit includes a division node that divides an input signal into first and second signals, a main amplifier that amplifies the first signal and outputs an amplified first signal as a third signal, a first peak amplifier that amplifies the second signal, and outputs an amplified second signal as a fourth signal, and a combination node that combines the third signal and the fourth signal and outputs a combined signal to an output terminal as an output signal, wherein a first electrical length of a sum of an electrical length between the division node and the main amplifier and an electrical length between the main amplifier and the combination node is shorter than a second electrical length of a sum of an electrical length between the division node and the first peak amplifier and an electrical length between the first peak amplifier and the combination node.

### CROSS REFERENCE TO RELATED APPLICATIONS

This application claims priority based on Japanese Patent Application No. 2023-202824 filed on Nov. 30, 2023, and the entire contents of the Japanese patent applications are incorporated herein by reference.

### FIELD

A certain aspect of the embodiments is related to a Doherty amplifier circuit.

### BACKGROUND

There has been known an N-way Doherty amplifier circuit (N is 3 or more) using a main amplifier and two or more peak amplifiers (for example, Patent Document 1: U.S. Pat. No. 8,022,760, and Patent document 2: U.S. Pat. No. 10,601,375).

### SUMMARY

A Doherty amplifier circuit according to the present disclosure includes a division node that divides an input signal into a first signal and a second signal; a main amplifier that includes a first GaN HEMT, amplifies the first signal, and outputs an amplified first signal as a third signal; a first peak amplifier that includes a second GaN HEMT, amplifies the second signal, and outputs an amplified second signal as a fourth signal; and a combination node that combines the third signal and the fourth signal and outputs a combined signal to an output terminal as an output signal; wherein a first electrical length of a sum of an electrical length between the division node and the main amplifier and an electrical length between the main amplifier and the combination node is shorter than a second electrical length of a sum of an electrical length between the division node and the first peak amplifier and an electrical length between the first peak amplifier and the combination node.

### BRIEF DESCRIPTION OF DRAWINGS

FIG. 1 is a block diagram of a Doherty amplifier circuit according to a first embodiment.

FIG. 2 is a schematic diagram illustrating a probability with respect to an output power Pout, an output power Pout of each amplifier with respect to an input power Pin, a gain of each amplifier with respect to an input power Pin, and an overall gain with respect to an input power Pin in the first embodiment.

FIG. 3 is a cross-sectional view of a GaN HEMT of the first embodiment.

FIG. 4 is a diagram illustrating a phase with respect to an input power Pin in the GaN HMET.

FIG. 5 is a diagram illustrating an output power Pout of each amplifier with respect to an input power Pin and a phase of each amplifier with respect to an input power Pin.

FIG. 6 is a diagram illustrating an output power Pout of each amplifier with respect to an input power Pin and a phase of each amplifier with respect to an input power Pin.

FIG. 7 is a diagram for explaining a phase adjustment method in the first embodiment.

### DETAILED DESCRIPTION OF EMBODIMENTS

However, in the Doherty amplifier circuit, when the phases of the signals at a combining node where the signals amplified by the amplifiers are combined are different from each other, characteristics such as a gain are deteriorated.

An object of the present disclosure is to suppress the deterioration of the characteristics.

### Details of Embodiments of the Present Disclosure

First, the contents of the embodiments of this disclosure are listed and explained.

(1) A Doherty amplifier circuit according to the present disclosure includes a division node that divides an input signal into a first signal and a second signal; a main amplifier that includes a first GaN HEMT, amplifies the first signal, and outputs an amplified first signal as a third signal; a first peak amplifier that includes a second GaN HEMT, amplifies the second signal, and outputs an amplified second signal as a fourth signal; and a combination node that combines the third signal and the fourth signal and outputs a combined signal to an output terminal as an output signal; wherein a first electrical length of a sum of an electrical length between the division node and the main amplifier and an electrical length between the main amplifier and the combination node is shorter than a second electrical length of a sum of an electrical length between the division node and the first peak amplifier and an electrical length between the first peak amplifier and the combination node. Therefore, the characteristics can be improved.

(2) In the above (1), a difference between the second electrical length and the first electrical length may be 2° or more and 20° or less in terms of a phase at a center frequency of an operating band. This makes it possible to further improve the characteristics.

(3) In the above (2), when an input power of the input signal is a power at which the main amplifier and the first peak amplifier operate, a difference between a value obtained by converting a difference between the second electric length and the first electric length into a phase at the center frequency, and a difference between an amount of phase change when a signal of the center frequency passes through the main amplifier and an amount of phase change when a signal of the center frequency passes through the first peak amplifier may be 2° or less. This makes it possible to further improve the characteristics.

(4) In the above (1), the Doherty amplifier circuit may further includes a second peak amplifier that includes a third GaN HEMT, amplifies a fifth signal, and outputs an amplified third signal as a sixth signal.

The division node may divide the input signal into the first signal, the second signal and the fifth signal. The combination node may combine the third signal, the fourth signal, and the sixth signal, and output a combined signal to the output terminal as the output signal. An input power of the input signal to turn on the second peak amplifier may be larger than an input power of the input signal to turn on the first peak amplifier. A third electrical length, which is a sum of an electrical length between the division node and the second peak amplifier and an electrical length between the second peak amplifier and the combination node, may be longer than the second electrical length. This makes it possible to reduce the phase difference between the third signal, the fourth signal, and the sixth signal at the combination. Therefore, the characteristics can be improved.

(5) In the above (4), a difference between the second electrical length and the first electrical length may be 2° or more and 20° or less in terms of a phase at a center frequency of an operating band, and a difference between the third electric length and the second electric length may be 2° or more and 20° or less in terms of a phase at the center frequency. This makes it possible to further improve the characteristics.

(6) In the above (5), a difference between a value obtained by converting a difference between the second electric length and the first electric length into a phase at the center frequency, and a difference between an amount of phase change when a signal at the center frequency passes through the main amplifier and an amount of phase change when a signal at the center frequency passes through the first peak amplifier may be 2° or less. A difference between a value obtained by converting a difference between the third electric length and the second electric length into a phase at the center frequency, and a difference between an amount of phase change when the signal at the center frequency passes through the first peak amplifier and an amount of phase change when a signal at the center frequency passes through the second peak amplifier may be 2° or less. This makes it possible to further improve the characteristics.

(7) In any of the above (4) to (6), the Doherty amplifier circuit may further includes: a first impedance converter connected between the first peak amplifier and the combination node; a second impedance converter connected between the second peak amplifier and the combination node; a first phase adjuster connected between the division node and the main amplifier; a second phase adjuster connected between the division node and the first peak amplifier; and a third phase adjuster connected between the division node and the second peak amplifier. An electrical length of the second phase adjuster may be 2° or more and 20° or less in terms of a phase of a signal at a center frequency of an operating band, and an electrical length of the third phase adjuster may be 4° or more and 40° or less in terms of a phase of a signal at the center frequency. This facilitates the design of the second and third phase adjusters.

(8) In the above (7), no impedance converter may be provided between the main amplifier and the combination node, and an electrical length of the first phase adjuster may be 67.5° or more and 112.5° or less in terms of a phase of a signal at the center frequency. This facilitates the design of the first phase adjuster.

Specific examples of a Doherty amplifier circuit according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

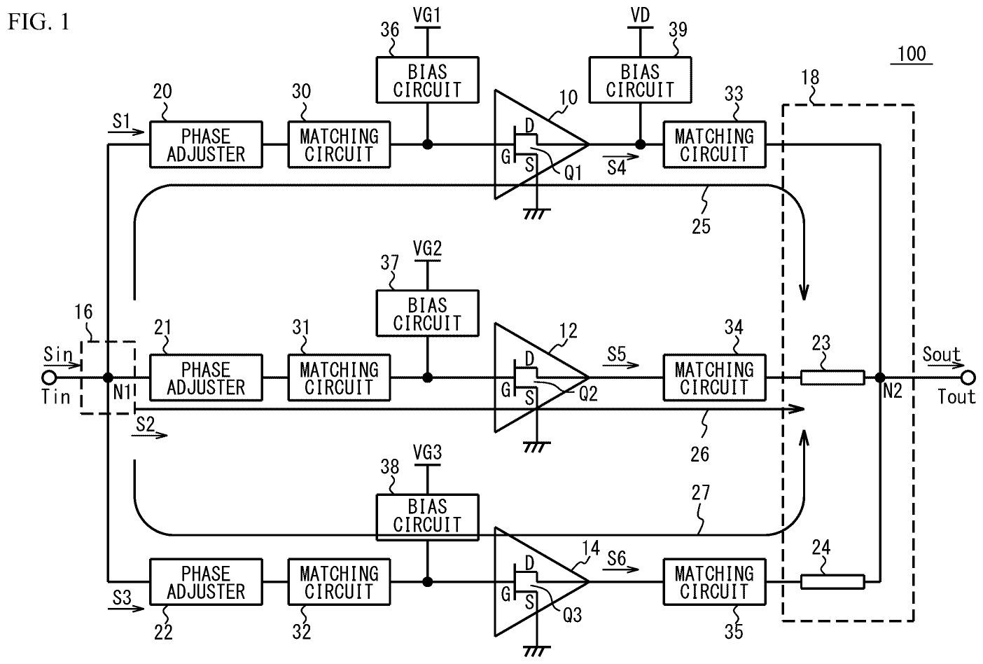

As an example of the Doherty amplifier circuit, a description will be given of a high-output high-frequency amplifier circuit used in a base station of mobile communication. In this case, the frequency of the high-frequency signal is, for example, 0.5 GHz or more and 10 GHz or less. FIG. 1 is a block diagram of the Doherty amplifier circuit according to a first embodiment.

As illustrated in FIG. 1, in a Doherty amplifier circuit 100, a main amplifier 10, a peak amplifier 12 (first peak amplifier), and a peak amplifier 14 (second peak amplifier) are connected in parallel between a division node N1 of a divider 16 and a combination node N2 of a combiner 18. Paths 25 to 27 are paths from the division node N1 to the combination node N2 through the main amplifier 10 and the peak amplifiers 12 and 14, respectively. Thus, the Doherty amplifier circuit 100 is a three-way amplifier circuit. The Doherty amplifier circuit may be an N-way Doherty amplifier circuit having one peak amplifier or three or more peak amplifiers.

A high-frequency signal is input to the input terminal Tin as an input signal Sin. The divider 16 divides the input signal Sin input to the input terminal Tin into the signals S1 (first signal), S2 (second signal), and S3 (fifth signal). The divider 16 is, for example, a Wilkinson divider. The divider 16 has the division node N1 at which the signals S1, S2 and S3 are divided.

The path 25 includes a phase adjuster 20 (first phase adjuster), a matching circuit 30, a bias circuit 36, the main amplifier 10, a bias circuit 39, and a matching circuit 33. The path 26 includes a phase adjuster 21 (second phase adjuster), a matching circuit 31, a bias circuit 37, the peak amplifier 12, a matching circuit 34, and an impedance converter 23 (first impedance converter). The path 27 includes a phase adjuster 22 (third phase adjuster), a matching circuit 32, a bias circuit 38, the peak amplifier 14, a matching circuit 35, and an impedance converter 24 (second impedance converter).

The matching circuits 30 to 32 match impedances viewed from the divider 16 toward the matching circuits 30 to 32 with impedances viewed from the matching circuits 30 to 32 toward the main amplifier 10 and the peak amplifiers 12 and 14, respectively. The bias circuits 36 to 38 supply gate bias voltages VG1 to VG3 to the gates G of the main amplifier 10 and the peak amplifiers 12 and 14, respectively.

The phase adjuster 20 adjusts the phase of the signal S1 in order to align the phase of the signal S4 with the phases of the signals S5 and S6 which are changed by the impedance converters 23 and 24. The phase adjusters 21 and 22 adjust a phase difference between the main amplifier 10 and the peak amplifiers 12 and 14, which will be described later. The phase adjusters 20 to 22 are transmission lines such as microstrip lines or coplanar lines, and the phases can be adjusted by setting the electrical lengths of the transmission lines to desired lengths.

The main amplifier 10 and the peak amplifiers 12 and 14 amplify the signals S1, S2 and S3, respectively, and output the amplified signals S4 (third signal), S5 (fourth signal) and S6 (sixth signal), respectively. The bias circuit 39 supplies a drain bias voltage VD to the drains D of the main amplifier 10 and the peak amplifiers 12 and 14. The matching circuits 33 to 35 match impedances as viewed from the matching circuits 33 to 35 toward the main amplifier 10 and the peak amplifiers 12 and 14 with impedances as viewed from the combiner 18 toward the matching circuits 33 to 35, respectively.

The combiner 18 includes the combination node N2 and the impedance converters 23 and 24. The impedance converter 23 has a first end electrically connected to the peak amplifier 12 through the matching circuit 34 and a second end electrically connected to the combination node N2. The impedance converter 24 has a first end electrically connected to the peak amplifier 14 through the matching circuit 35 and a second end electrically connected to the combination node N2. The combination node N2 combines the signals S4 to S6 and outputs the combined signal to the output terminal Tout as an output signal Sout.

The impedance converters 23 and 24 convert impedances on the real axis of the Smith chart viewed from the matching circuits 34 and 35 toward the impedance converters 23 and 24 into impedances at different locations on the real axis of the Smith chart viewed from the impedance converters 23 and 24 toward the combination node N2. When the peak amplifier 12 does not operate, the impedance converter 23 sets the impedance viewed from the combination node N2 toward the peak amplifier 12 to infinity. When the peak amplifier 14 does not operate, the impedance converter 24 sets the impedance viewed from the combination node N2 toward the peak amplifier 14 to infinity.

The impedance converters 23 and 24 are transmission lines, such as microstrip lines or coplanar lines, and are ¼ wavelength lines at the center frequency of the operating band. The electrical length of the ¼ wavelength line is not strictly limited to the ¼ wavelength. The ¼ wavelength lines only need to have electrical lengths that serve as the impedance converters 23 and 24. For example, the electric length of the ¼ wavelength line may be 3/16 wavelength or more and 5/16 wavelength or less, or 7/32 wavelength or more and 9/32 wavelength or less. The impedance on the real axis in the Smith chart does not have to be strictly on the real axis (i.e., a reactance component is 0). An absolute value of the reactance component of the impedance may be 0.2 times or less or 0.1 times or less a resistance component.

The main amplifier 10 and the peak amplifiers 12 and 14 include transistors Q1 to Q3, respectively. The transistors Q1 to Q3 are, for example, GaN HEMTs (Gallium Nitride High Electron Mobility Transistor). The sources S of the transistors Q1 to Q3 are grounded, the signals S1 to S3 are input to the gates G, and the signals S4 to S6 are output from the drains D.

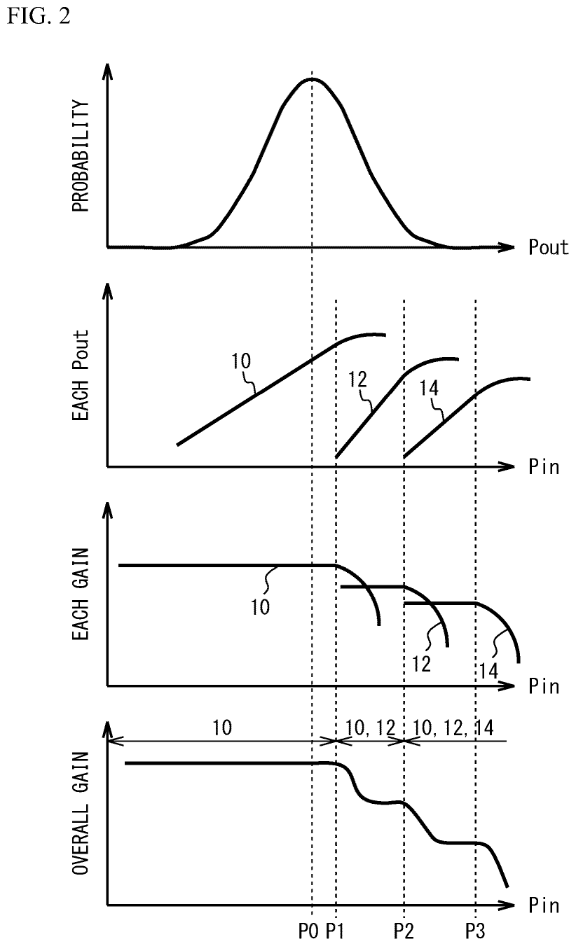

FIG. 2 is a schematic diagram illustrating a probability with respect to an output power Pout, an output power Pout of each amplifier with respect to an input power Pin, a gain of each amplifier with respect to an input power Pin, and an overall gain with respect to an input power Pin in the first embodiment.

The probability is a probability of a modulated wave signal of the high-frequency signal for mobile communication amplified by the Doherty amplifier circuit 100. That is, it is a probability that the Doherty amplifier circuit 100 outputs a certain output power Pout. Each Pout is an output power Pout of each of the main amplifier 10 and the peak amplifiers 12 and 14. Each gain is a power gain of each of the main amplifier 10 and the peak amplifiers 12 and 14. The overall gain is a power gain of the output power Pout of the output signal Sout with respect to the input power Pin of the input signal Sin. The Pin and Pout are expressed in dB. The gain of the main amplifier 10 at a power P1 or less of each gain is larger than the gain of the peak amplifier 12 at the power P1 or more and a power P2 or less. That is, the inclination of Pout with respect to the input power Pin at the power P1 or less of the main amplifier 10 is larger than the inclination of Pout with respect to the input power Pin at the power P1 or more and P2 or less of the peak amplifier 12. However, FIG. 2 is a schematic diagram, and illustrates that the inclination of Pout with respect to the input power Pin at the power P1 or less of the main amplifier 10 is smaller than the inclination of Pout with respect to the input power Pin at the power P1 or more and P2 or less of the peak amplifier 12.

As illustrated in FIG. 2, when the output power Pout is the power P0, the probability of the modulated wave is maximum. That is, when the modulated wave signal is output, the time when the output power Pout is the power P0 is the longest. The main amplifier 10 is an A class or AB class amplifier, and the peak amplifiers 12 and 14 are C class amplifiers. The input power Pin at which the peak amplifier 12 is turned on is larger than the input power Pin at which the main amplifier 10 is turned on, and the input power Pin at which the peak amplifier 14 is turned on is larger than the input power Pin at which the peak amplifier 12 is turned on. Such an operation can be realized by making the gate bias voltage VG2 of the transistor Q2 larger in negative value than the gate bias voltage VG1 of the transistor Q1, and making the gate bias voltage VG3 of the transistor Q3 larger in negative value than the gate bias voltage VG2 of the transistor Q2.

The main amplifier 10 operates, but the peak amplifiers 12 and 14 do not operate, until the input power Pin of the input signal Sin becomes large, the input power Pin exceeds the power P0, and the power P1 is reached. When the input power Pin is equal to or less than the power P1, the output power Pout of the main amplifier 10 increases linearly as the input power Pin increases. Therefore, when the input power Pin is equal to or less than the power P0, each gain and the overall gain are substantially constant.

When the input power Pin is equal to or greater than the power P1 and equal to or less than the power P2, the main amplifier 10 and the peak amplifier 12 operate, but the peak amplifier 14 does not operate. In this range, the main amplifier 10 is saturated. Therefore, the gain of the main amplifier 10 is reduced. This also reduces the overall gain. Since the peak amplifier 12 operates in class C, the gain of the peak amplifier 12 between the powers P1 and P2 is lower than the gain of the main amplifier 10 at the power P1 or lower. The saturation power of the peak amplifier 12 is smaller than the saturation power of the main amplifier 10.

When the input power Pin is equal to or greater than the power P2 and equal to or less than the power P3, all of the main amplifier 10 and the peak amplifiers 12 and 14 operate. In this range, the peak amplifier 12 is saturated in addition to the main amplifier 10. Therefore, the gain of the peak amplifier 12 is reduced. This also reduces the overall gain. Since the peak amplifier 14 is negatively larger than the operating point of the peak amplifier 12, the gain of the peak amplifier 14 between the powers P2 and P3 is lower than the gain of the peak amplifier 12 between the powers P1 and P2. The saturation power of the peak amplifier 14 is smaller than the saturation power of the peak amplifier 12.

When the input power Pin is equal to or greater than the power P3, the peak amplifier 14 is saturated in addition to the main amplifier 10 and the peak amplifier 12. Therefore, the gain of the peak amplifier 14 is reduced. This also reduces the overall gain.

The product of the probability and the overall gain corresponds to the gain of the modulated wave. To improve the gain of the modulated wave, the overall gain at Pout with high probability is improved.

### [Description of GaN HEMT]

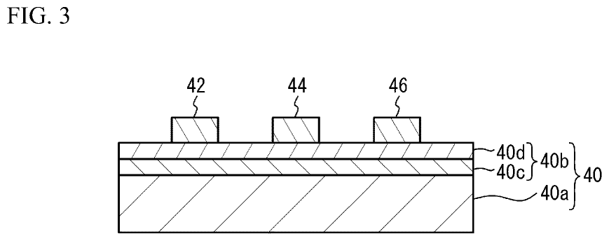

FIG. 3 is a cross-sectional view of the GaN HEMT of the first embodiment. As illustrated in FIG. 3, the GaN HEMT has a source electrode 42, a gate electrode 44, and a drain electrode 46 provided on a substrate 40. The substrate 40 includes a substrate 40a and a semiconductor layer 40b provided on the substrate 40a. The semiconductor layer 40b includes a transit layer 40c provided on the substrate 40a and a barrier layer 40d provided on the transit layer 40c. The substrate 40a is, for example, a silicon carbide (SiC) substrate, a sapphire substrate, or a gallium nitride (GaN) substrate. The semiconductor layer 40b is a nitride semiconductor layer, the transit layer 40c is, for example, a gallium nitride layer, and the barrier layer 40d is, for example, an aluminum gallium nitride layer.

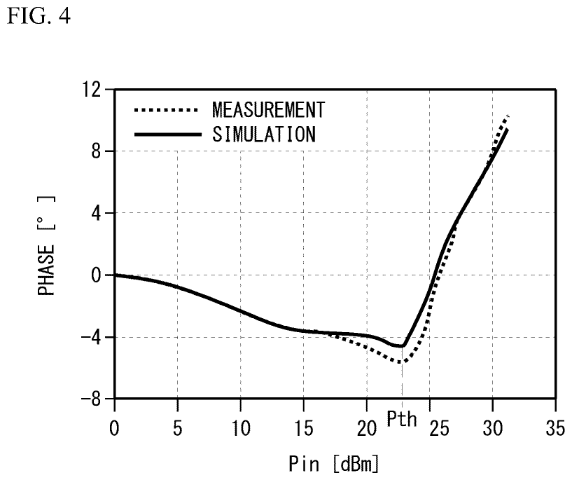

FIG. 4 is a diagram illustrating a phase with respect to an input power Pin in the GaN HMET, and is a diagram illustrating an AM (Amplitude Modulation)-PM (Phase Modulation) characteristic. The input power Pin is the power of the high-frequency signal at the center frequency of the operating band input to the gate of the GaN HEMT. The phase is a difference between the phases of the high-frequency signal input to the gate and the high-frequency signal output from the drain, and the phase when the input power Pin is 0 dBm is defined as 0°. FIG. 4 illustrates a measurement result and a simulation result. The values of the input power Pin and the phase are examples because they vary depending on the structure such as the gate width of the GaN HEMT.

As illustrated in FIG. 4, as the input power Pin increases from 0 dBm, the phase moves in a negative direction. When the input power Pin exceeds a power Pth (23 dBm), the phase moves in a positive direction. The absolute value of the gradient of the phase with respect to the input power Pin is larger when the input power Pin is equal to or more than Pth than when the input power Pin is equal to or less than Pth.

### [Description of Phase of Each Amplifier]

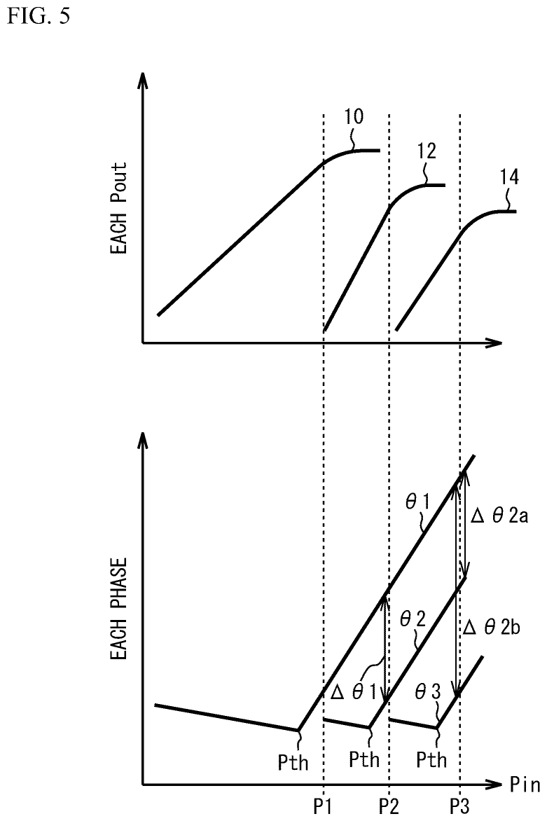

FIG. 5 is a diagram illustrating an output power Pout of each amplifier with respect to an input power Pin and a phase of each amplifier with respect to an input power Pin. The input power Pin corresponds to the input power of the input signal Sin in FIG. 1. Each Pout is the output power of each of the main amplifier 10 and the peak amplifiers 12 and 14. The phases of the main amplifier 10 and the peak amplifiers 12 and 14 correspond to amounts θ1, θ2, and θ3 of phase change when the signals at the center frequency of the operating band passes through the main amplifier 10 and the peak amplifiers 12 and 14, respectively. A positive increase in the amount θ1 to θ3 of phase change indicates that the phase is advanced, and corresponds to an increase in the electrical length.

As illustrated in FIG. 5, the powers Pth at the amounts θ1 to θ3 of phase change are slightly smaller than the power P1 to P3, respectively. Therefore, when the input power Pin is the power P2, the phase difference between the main amplifier 10 and the peak amplifier 12 is Δθ1. When the input power Pin is the power P3, the phase difference between the main amplifier 10 and the peak amplifier 12 is Δθ2a, and the phase difference between the main amplifier 10 and the peak amplifier 14 is Δθ2b. The Δθ1 and Δθ2a are substantially equal to each other, but may be different from each other.

In this way, when the phase differences Δθ1, Δθ2a and Δθ2b exist, the power of the output signal Sout is reduced when the signals S4 to S6 are combined at the combination node N2, and the overall gain is reduced.

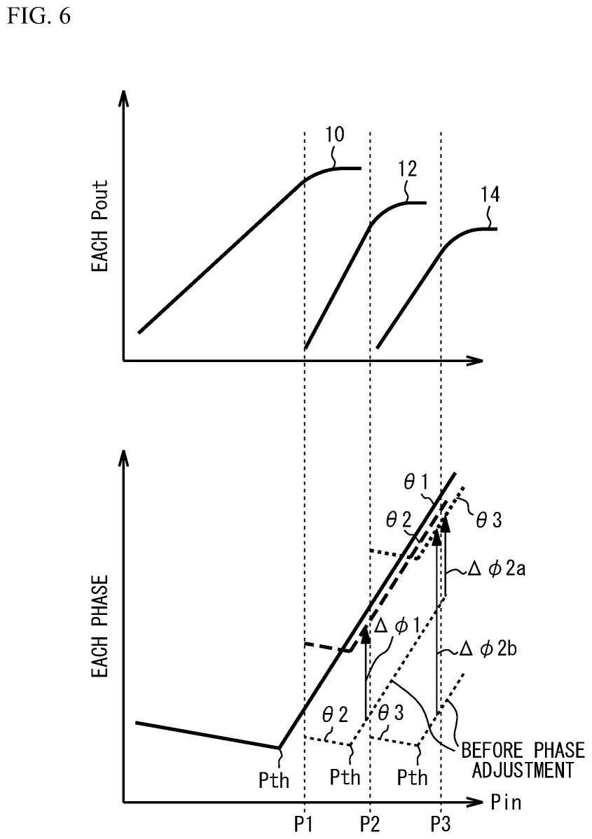

FIG. 6 is a diagram illustrating an output power Pout of each amplifier with respect to an input power Pin and a phase of each amplifier with respect to an input power Pin. Thin broken lines indicate states before the phases are adjusted by the phase adjusters 21 and 22.

As illustrated in FIG. 6, the phase of the path 26 is advanced by Δφ1 when the input power Pin is the power P2. The phases of the paths 26 and 27 are advanced by Δφ2a and Δφ2b, respectively, when the input power Pin is the power P3. As a result, the phases of the main amplifier 10 and the peak amplifier 12 are substantially aligned at the power P2. At the power P3, the phases of the main amplifier 10 and the peak amplifier 12 are substantially aligned, and the phases of the main amplifier 10 and the peak amplifier 14 are substantially aligned.

### [Phase Adjustment Method]

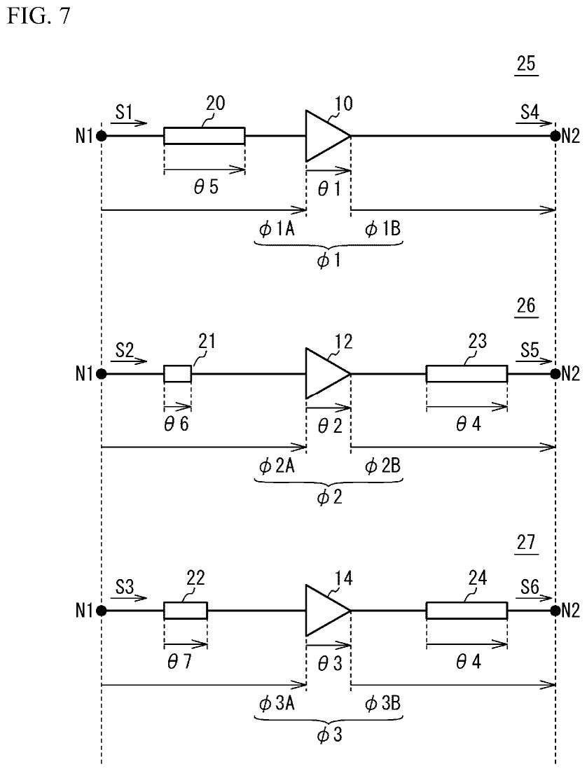

FIG. 7 is a diagram for explaining a phase adjustment method in the first embodiment. FIG. 7 illustrates each of the paths 25 through 27 between the division node N1 and the combination node N2. The illustration of the matching circuits 30 to 35 and the bias circuits 36 to 39 are omitted.

As the amount θ1 of phase change increases, the phase rotates more, i.e., the phase is advanced, which corresponds to the electrical length of the signal passing through the main amplifier 10 becoming longer. Phases φ1A, φ2A, and φ3A are amounts obtained by converting the electrical lengths between the division node N1, and the main amplifier 10 and the peak amplifiers 12 and 14 into phases at the center frequency of the operating band, respectively. Phases φ1B, φ2B, and φ3B are amounts obtained by converting the electrical lengths between the combination node N2, and the main amplifier 10, the peak amplifiers 12 and 14 into phases at the center frequency of the operating band, respectively. An amount φ1 of phase change is the sum of φ1A and φ1B, an amount φ2 of phase change is the sum of φ2A and φ2B, and an amount φ3 of phase change is the sum of φ3A and φ3B.

The amount of phase change when the signals pass through the impedance converters 23 and 24 at the center frequency of the operating band of the impedance converters 23 and 24 is θ4. Therefore, an amount of the phase adjustment of the phase adjuster 20 is set to θ5. For example, when the phase adjuster 20 is formed of a transmission line, the electrical length of the transmission line is set to a length corresponding to the adjustment amount θ5. For example, θ5 is 90°. Thus, the amount of phase change due to the impedance converters 23 and 24 can be adjusted by the phase adjuster 20.

However, as illustrated in FIG. 5, the phases of the signals passing through the main amplifier 10 and the peak amplifiers 12 and 14 are different from each other. Therefore, an amount θ6 of the phase adjustment of the phase adjuster 21 is set to Δθ1 and Δθ2a. An amount θ7 of the phase adjustment of the phase adjuster 22 is set to Δθ2b. As a result, as illustrated in FIG. 6, the differences in phase when the signals pass through the main amplifier 10 and the peak amplifiers 12 and 14 can be adjusted. When Δθ1 and Δθ2a are different from each other, the adjustment amount θ6 may be set to a value between Δθ1 and Δθ2a. In order to improve the gain of the modulated wave, the adjustment of the phase in the power P2 is more important than the adjustment of the phase in the power P3. Therefore, the adjustment amount θ6 may be set to Δθ1.

According to the first embodiment, a first electrical length (corresponding to φ1), which is the sum of an electrical length (corresponding to φ1A) between the division node N1 and the main amplifier 10 and an electrical length (corresponding to φ1B) between the main amplifier 10 and the combination node N2, is shorter than a second electrical length (corresponding to φ2), which is the sum of an electrical length (corresponding to φ2A) between the division node N1 and the peak amplifier 12 and an electrical length (corresponding to φ2B) between the peak amplifier 12 and the combination node N2. In the GaN HEMT, as illustrated in FIG. 5, when the input power Pin is the power P2 or P3 at which the main amplifier 10 and the peak amplifier 12 operate, the amount θ1 of phase change of the main amplifier 10 is larger than the amount θ2 of phase change of the peak amplifier 12. Therefore, the first electrical length corresponding to φ1 of the path 25 is made shorter than the second electrical length corresponding to φ2 of the path 26. This makes it possible to reduce the phase difference between the signals S4 and S5 at the combination node N2. Therefore, the overall gain when the input power Pin is the power P2 can be improved, and the characteristics can be improved.

A difference between the second electrical length and the first electrical length can be 2° or more and 20° or less, or 5° or more and 15° or less, in terms of the phase (φ2−φ1) at the center frequency of the operating band. This makes it possible to further reduce the phase difference between the signals S4 and S5 at the combination node N2. Therefore, the characteristics can be further improved.

When the input power Pin is the power P2 or P3, the difference between the difference Δθ1 between the amount θ1 of phase change when the signal passes through the main amplifier 10 and the amount θ2 of phase change when the signal pass through the peak amplifier 12 and the difference Δφ1 or Δφ2a can be 2° or less, 1.5° or less, or 1° or less. This makes it possible to further reduce the phase difference between the signals S4 and S5 at the combination node N2. Therefore, the characteristics can be further improved.

A third electrical length (corresponding to φ3), which is the sum of an electrical length (corresponding to φ3A) between the division node N1 and the peak amplifier 14 and an electrical length (corresponding to φ3B) between the peak amplifier 14 and the combination node N2, is longer than the first electrical length (corresponding to φ1) and longer than the second electrical length (corresponding to φ2). In the GaN HEMT, as illustrated in FIG. 5, when the input power Pin is the power P3 at which the main amplifier 10 and the peak amplifiers 12 and 14 operate, the amount θ2 of phase change of the peak amplifier 12 is larger than the amount θ3 of phase change of the peak amplifier 14. Therefore, the third electrical length corresponding to φ3 of the path 27 is made longer than the second electrical length corresponding to φ2 of the path 26. This makes it possible to reduce the phase difference between the signals S5 and S6 at the combination node N2. Therefore, the overall gain when the input power Pin is the power P3 can be improved, and the characteristics can be improved.

A difference between the third electrical length and the second electrical length can be 2° or more and 20° or less, and 5° or more and 15° or less, in terms of the phase (φ3−φ2) at the center frequency of the operating band. This makes it possible to further reduce the phase difference between the signals S5 and S6 at the combination node N2. Therefore, the characteristics can be further improved.

When the input power Pin is the power P3, a difference between a difference (Δθ2b−Δθ2a) between the amount θ2 of phase change when the signal passes through the peak amplifier 12 and the amount θ3 of phase change when the signal passes through the peak amplifier 14 and a difference (Δφ2b−Δφ2a) can be 2° or less, 1.5° or less, or 1° or less. This makes it possible to further reduce the phase difference between the signals S5 and S6 at the combination node N2. Therefore, the characteristics can be further improved.

In order to realize the above, the amount θ5 of phase adjustment of the phase adjuster 20 corresponds to the amount θ4 of phase change of the signals S5 and S6 by the impedance converters 23 and 24. The amount θ6 of phase adjustment of the phase adjuster 21 corresponds to Δθ1 and 4θ2a when the input power Pin is the power P2 or P3. The amount of the phase adjustment of the phase adjuster 22 corresponds to Δθ2b when the input power Pin is the power P3.

When the impedance converters 23 and 24 are provided, the electrical length of the phase adjuster 21 can be 2° or more and 20° or less or 5° or more and 15° or less in terms of the phase of the signal at the center frequency. The electrical length of the phase adjuster 22 can be 4° or more and 40° or less or 10° or more and 30° or less in terms of the phase of the signal at the center frequency. Thus, when the Doherty amplifier circuit is designed, the electrical length of the phase adjuster 20 is set so as to adjust the phase differences corresponding to differences between the phases φ1B, φ2B, and φ3B. After that, the electrical length of the phase adjuster 21 is set so as to adjust the phase differences Δθ1 and Δθ2a between the main amplifier 10 and the peak amplifier 12. The phase adjuster 22 is set so as to adjust the phases difference Δθ2b between the peak amplifiers 12 and 14. This facilitates the design of the phase adjusters 21 and 22.

When no impedance converter is provided between the main amplifier 10 and the combination node N2, the electrical length of the phase adjuster 20 can be 67.5° or more and 112.5° or less, 78.75° or more and 101.25° or less, or 85° or more and 95° or less in terms of the phase of the signal at the center frequency of the operating band. Thereby, the electrical length of the phase adjuster 20 is set so as to adjust the electrical lengths of the impedance converters 23 and 24. This facilitates the design of the phase adjuster 20.

Although the three-way Doherty amplifier circuit has been described as an example, a two-way Doherty amplifier circuit in which the peak amplifier 14 and the impedance converter are not provided may be used. Alternatively, an N-way Doherty amplifier circuit in which N is 4 or more may be used. In this case, N−1 peak amplifiers may be provided.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A Doherty amplifier circuit comprising:
a division node that divides an input signal into a first signal and a second signal;
a main amplifier that includes a first GaN HEMT, amplifies the first signal, and outputs an amplified first signal as a third signal;
a first peak amplifier that includes a second GaN HEMT, amplifies the second signal, and outputs an amplified second signal as a fourth signal; and
a combination node that combines the third signal and the fourth signal and outputs a combined signal to an output terminal as an output signal;
wherein a first electrical length of a sum of an electrical length between the division node and the main amplifier and an electrical length between the main amplifier and the combination node is shorter than a second electrical length of a sum of an electrical length between the division node and the first peak amplifier and an electrical length between the first peak amplifier and the combination node.

2. The Doherty amplifier circuit according to claim 1, wherein
a difference between the second electrical length and the first electrical length is 2° or more and 20° or less in terms of a phase at a center frequency of an operating band.

3. The Doherty amplifier circuit according to claim 2, wherein
when an input power of the input signal is a power at which the main amplifier and the first peak amplifier operate, a difference between a value obtained by converting a difference between the second electric length and the first electric length into a phase at the center frequency, and a difference between an amount of phase change when a signal of the center frequency passes through the main amplifier and an amount of phase change when a signal of the center frequency passes through the first peak amplifier is 2° or less.

4. The Doherty amplifier circuit according to claim 1, further comprising
a second peak amplifier that includes a third GaN HEMT, amplifies a fifth signal, and outputs an amplified third signal as a sixth signal,
wherein the division node divides the input signal into the first signal, the second signal and the fifth signal,
the combination node combines the third signal, the fourth signal, and the sixth signal, and outputs a combined signal to the output terminal as the output signal,
an input power of the input signal to turn on the second peak amplifier is larger than an input power of the input signal to turn on the first peak amplifier, and
a third electrical length, which is a sum of an electrical length between the division node and the second peak amplifier and an electrical length between the second peak amplifier and the combination node, is longer than the second electrical length.

5. The Doherty amplifier circuit according to claim 4, wherein
a difference between the second electrical length and the first electrical length is 2° or more and 20° or less in terms of a phase at a center frequency of an operating band, and
a difference between the third electric length and the second electric length is 2° or more and 20° or less in terms of a phase at the center frequency.

6. The Doherty amplifier circuit according to claim 5, wherein
a difference between a value obtained by converting a difference between the second electric length and the first electric length into a phase at the center frequency, and a difference between an amount of phase change when a signal at the center frequency passes through the main amplifier and an amount of phase change when a signal at the center frequency passes through the first peak amplifier is 2° or less, and
a difference between a value obtained by converting a difference between the third electric length and the second electric length into a phase at the center frequency, and a difference between an amount of phase change when the signal at the center frequency passes through the first peak amplifier and an amount of phase change when a signal at the center frequency passes through the second peak amplifier is 2° or less.

7. The Doherty amplifier circuit according to claim 4, further comprising:
a first impedance converter connected between the first peak amplifier and the combination node;
a second impedance converter connected between the second peak amplifier and the combination node;
a first phase adjuster connected between the division node and the main amplifier;
a second phase adjuster connected between the division node and the first peak amplifier; and
a third phase adjuster connected between the division node and the second peak amplifier;
wherein an electrical length of the second phase adjuster is 2° or more and 20° or less in terms of a phase of a signal at a center frequency of an operating band, and
an electrical length of the third phase adjuster is 4° or more and 40° or less in terms of a phase of a signal at the center frequency.

8. The Doherty amplifier circuit according to claim 7, wherein
no impedance converter is provided between the main amplifier and the combination node, and
an electrical length of the first phase adjuster is 67.5° or more and 112.5° or less in terms of a phase of a signal at the center frequency.
